(19) United States
(12) Patent Application Publication
(10) Pub. No.: US 2024/0162276 A1
(43) Pub. Date: May 16, 2024

(54) DISPLAY AREA WITH PIXEL OPENING

(71) Applicant: CORNING INCORPORATED, CORNING, NY (US)

(72) Inventors: Dae youn Kim, Asan-si (KR); Dong Keun Shin, Gyeonggi-do (KR); Hong Yoon, Chungcheongnam-do (KR)

(21) Appl. No.: 18/551,077

(22) PCT Filed: Mar. 31, 2022
(86) PCT No.: PCT/US2022/022733

§ 371 Date: Sep. 18, 2023

(30) Foreign Application Priority Data
Apr. 2, 2021 (KR) 10-2021-0043476

(51) Int. Cl. H01L 27/15

(52) U.S. Cl. CPC H01L 27/156

(57) ABSTRACT

A display area (100a) includes a plurality of tiles each tile including an optically transparent layer (208). Each of the plurality of tiles includes a substrate (202) and a plurality of light sources (204′) positioned on the substrate. In addition, each of the plurality of tiles includes a non-transparent layer (206) extending between the transparent layer and the plurality of light sources. The non-transparent layer includes an opening (214) extending over an area between at least one of the plurality of light sources and the transparent layer. In addition, a seam extends between adjacent tiles of the plurality of tiles and the non-transparent layer extends across the seam.

### CROSS REFERENCE TO RELATED APPLICATIONS

This application claims the benefit of priority under 35 U.S.C. § 119 of Korean Patent Application Serial No. 10-2021-0043476, filed on Apr. 2, 2021, the content of which is relied upon and incorporated herein in its entirety.

### FIELD

The present disclosure relates generally to a display area and more particularly to a display area with a non-transparent layer having a pixel opening.

### BACKGROUND

Micro-LED displays typically include arrays of microscopic light emitting diodes (LEDs), which form individual pixel elements. Such displays can exhibit improved attributes with respect to, for example flexibility, electrical consumption, brightness, contrast, sharpness, and reliability. Such displays can include an array of panels or tiles, wherein a seam or gap typically exits between adjacent panels or tiles. Such seam or gap may be undesirably visible to a viewer, particularly in the case of large-sized display applications. Use of a circular polarizer can minimize seam or gap visibility, but its relatively low optical transmittance can result in a loss of display brightness. According, a need exists for additional technologies that can minimize seam or gap visibility in tiled micro-LED displays.

### SUMMARY

Embodiments disclosed herein include a display area. The display area includes a plurality of tiles arranged in an array, each of the plurality of tiles comprising an optically transparent layer comprising a first major surface and an opposing second major surface. Each of the plurality of tiles includes a substrate comprising a major surface facing the second major surface of the transparent layer. In addition, each of the plurality of tiles includes a plurality of light sources positioned on the major surface of the substrate. Each of the plurality of tiles also includes a non-transparent layer between the transparent layer and the plurality of light sources, the non-transparent layer comprising an opening extending over an area between at least one of the plurality of light sources and the transparent layer. A seam extends between adjacent tiles of the plurality of tiles; and the non-transparent layer extends across the seam.

Additional features and advantages of the embodiments disclosed herein will be set forth in the detailed description which follows, and in part will be readily apparent to those skilled in the art from that description or recognized by practicing the disclosed embodiments as described herein, including the detailed description which follows, the claims, as well as the appended drawings.

It is to be understood that both the foregoing general description and the following detailed description present embodiments intended to provide an overview or framework for understanding the nature and character of the claimed embodiments. The accompanying drawings are included to provide further understanding and are incorporated into and constitute a part of this specification. The drawings illustrate various embodiments of the disclosure, and together with the description serve to explain the principles and operations thereof.

### BRIEF DESCRIPTION OF THE DRAWINGS

FIG. 1 is a perspective view of a display area comprising a plurality of tiles in accordance with embodiments disclosed herein;

FIG. 2 is an enlarged view of a tile of the plurality of tiles of FIG. 1 in accordance with embodiments disclosed herein;

FIG. 3 is an enlarged view of area ‘A’ of the tile of FIG. 2 comprising a plurality of pixels in accordance with embodiments disclosed herein;

FIG. 4 is an enlarged view of a pixel of FIG. 3, showing a plurality of chips and a non-transparent layer with an opening in accordance with embodiments disclosed herein;

FIG. 5 is cross-sectional view of a display area taken along the line ‘B-B’ of FIG. 4 in accordance with embodiments disclosed herein;

FIG. 6 is a cross-sectional view of a display area in accordance with embodiments disclosed herein;

FIG. 7 is a cross-sectional view of a portion of display area in accordance with embodiments disclosed herein;

FIG. 8 is a cross-sectional view of a portion of a display area in accordance with embodiments disclosed herein;

FIG. 9 is a cross-sectional view of a portion of a display area in accordance with embodiments disclosed herein;

FIG. 10 is a cross-sectional view of a portion of a display area in accordance with embodiments disclosed herein;

FIG. 11 is a cross-sectional view of a portion of a display area in accordance with embodiments disclosed herein;

FIG. 12 is a cross-sectional view of a portion of a display area in accordance with embodiments disclosed herein;

FIG. 13 is a cross-sectional view of a portion of a display area in accordance with embodiments disclosed herein;

FIG. 14 is a cross-sectional view of a portion of a display area in accordance with embodiments disclosed herein;

FIG. 15 is a chart showing reflectance as a function of pixel open area and transparent layer refractive index;

FIG. 16 is a chart showing reflectance in accordance with varying embodiments disclosed herein; and

FIG. 17 is a chart showing reflectance as a function of transparent layer thickness in accordance with embodiments disclosed herein.

### DETAILED DESCRIPTION

Reference will now be made in detail to the present preferred embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, for example by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

As used herein, the term “transparent” refers to a material or layer having an optical transmittance of at least about 30 percent over a length of 500 millimeters in the visible region of the spectrum (about 420-750 nanometers).

As used herein, the term “non-transparent” refers to a material or layer having an optical transmittance of less than about 1 percent over a length of 500 millimeters in the visible region of the spectrum (about 420-750 nanometers).

As used herein, the term “anti-reflective” refers to a material, layer, or coating having a refractive index of greater than about 1.0 and less than about 1.4.

As used herein, the term “tinted” refers to a material, layer, or coating that has been treated with an additional material, layer, or coating such that the transmission of light through the material, layer, or coating is less than the transmission of light through the same material, layer, or coating that has not been treated with the additional material, layer, or coating.

As used herein, the term “a material with transformable transparency” refers to a material that undergoes a change in light transparency upon exposure to heat and/or light.

As used herein, the term “reflectance value” refers to the fraction or percentage of light emitted from light sources of a display area that is reflected back to the light sources.

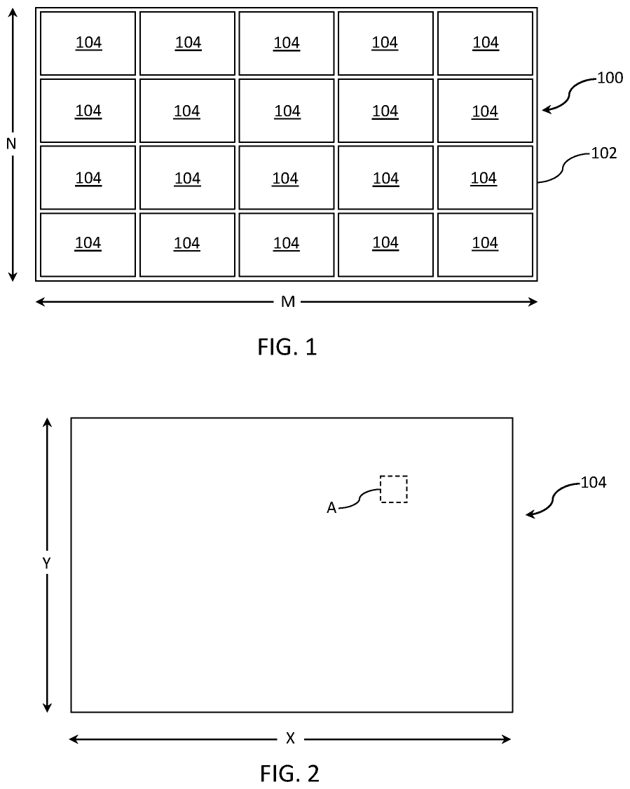

FIG. 1 shows a perspective view of a display area 100 comprising a plurality of tiles 104 in accordance with embodiments disclosed herein. As shown in FIG. 1, plurality of tiles 104 are positioned in a M×N array on base plate 102. Tiles 104 can, for example, be components of a micro-LED display and while FIG. 1 shows a display area 100 comprising 20 tiles 104, embodiments disclosed herein include display areas comprising any number of tiles 104.

FIG. 2 shows an enlarged view of a tile 104 of the plurality of tiles 104 of FIG. 1 in accordance with embodiments disclosed herein. While not limited to any particular geometry, in certain exemplary embodiments, tile can have a rectangular shape, with an X dimension ranging, for example, from about 50 millimeters to about 500 millimeters, such as from about 100 millimeters to about 300 millimeters, including about 200 millimeters, and a Y dimension ranging, for example, from about 40 millimeters to about 400 millimeters, such as from about 80 millimeters to about 250 millimeters, including about 150 millimeters.

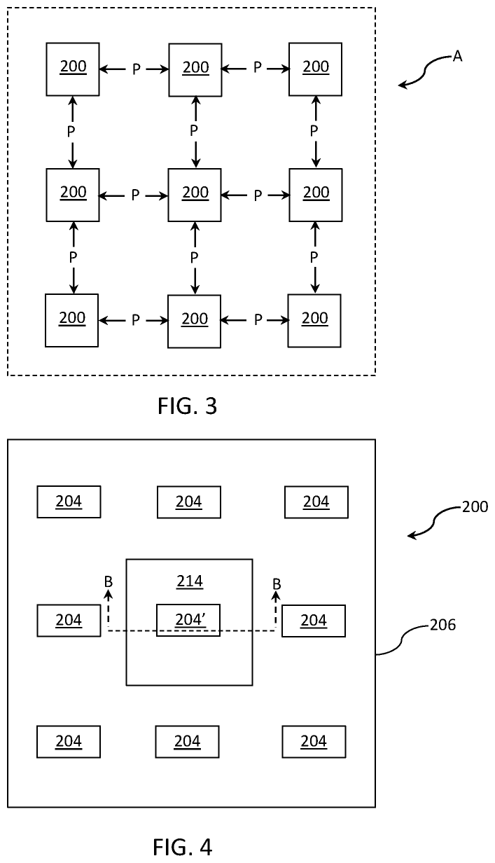

FIG. 3 shows an enlarged view of area ‘A’ of the tile of FIG. 2 comprising a plurality of pixels 200 in accordance with embodiments disclosed herein. A lateral distance between immediately adjacent pixels 200 (shown as distance ‘P’ in FIG. 3) is defined as a pixel pitch. In certain exemplary embodiments, the pixel pitch can be from about 100 micrometers to about 500 micrometers, such as from about 200 to about 400 micrometers.

FIG. 4 shows an enlarged view of a pixel 200 of FIG. 3, showing a plurality of chips 204 (e.g., LED chips) and a non-transparent layer 206 with an opening 214 in accordance with embodiments disclosed herein. Included among plurality of chips 204 is a red-green-blue (RGB) chip 204′ (e.g., a RGB LED chip). As shown in FIG. 4, opening 214 extends over an area comprising the RGB chip 204′ while non-transparent layer 206 extends over an area comprising a plurality of other chips 204. And while opening 214 is showing as having a rectangular (e.g., square) shape, embodiments disclosed herein include those in which opening 214 may have other shapes such as other polygonal shapes (e.g., triangular, etc.) or circular or elliptical shapes.

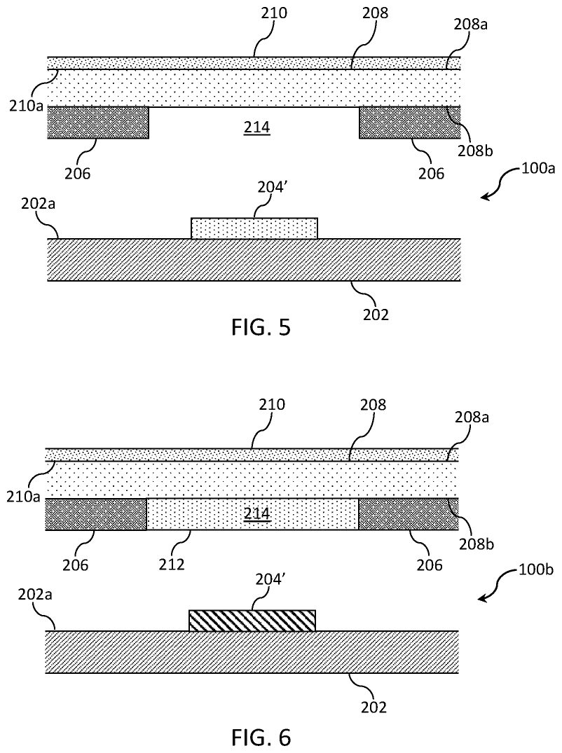

FIG. 5 shows a cross-sectional view of a display area 100a taken along the line ‘B-B’ of FIG. 4 in accordance with embodiments disclosed herein. Display area 100a includes an optically transparent layer 208 comprising a first major surface 208a and an opposing second major surface 208b. Display area 100a also includes a substrate 202 comprising a major surface 202a facing the second major surface 208b of the transparent layer 208. At least one light source 204′ (e.g., a RGB LED chip) of a plurality of light sources (e.g., LEDs) is positioned on the major surface 202a of the substrate 202. In addition, a non-transparent layer 206 extends between the transparent layer 208 and the at least one light source 204′. The non-transparent layer 206 includes opening 214 extending over an area between the at least one light source 204′ and the transparent layer 208. The display area 100a also includes an anti-reflective (AR) layer 210. The AR layer comprises a major surface 210a facing the first major surface 208a of the transparent layer 208.

FIG. 6 shows a cross-sectional view of a display area 100b in accordance with embodiments disclosed herein. The display area 100b of FIG. 6 is similar to the display area 100a of FIG. 5 except display area 100b includes a second transparent layer 212 that extends across opening 214 and between the transparent layer 208 and the at least one light source 204′.

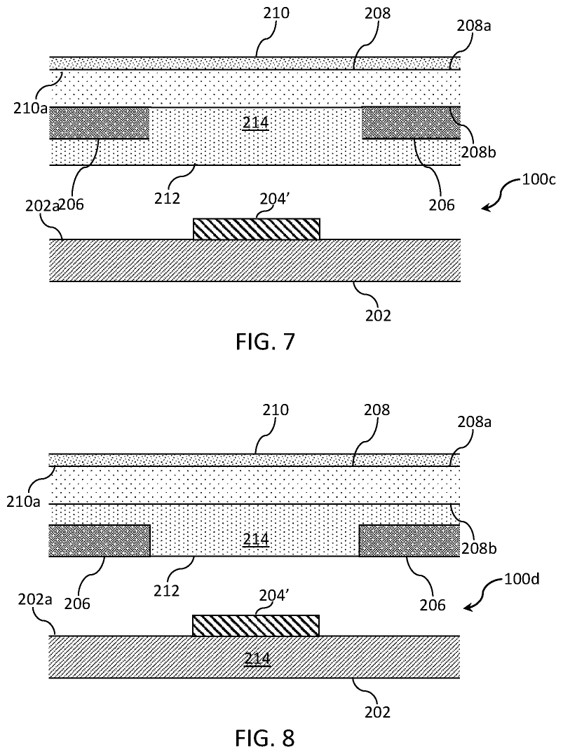

FIG. 7 shows a cross-sectional view of a display area 100c in accordance with embodiments disclosed herein. The display area 100c of FIG. 7 is similar to the display area 100b of FIG. 6 except second transparent layer 212 extends across not only opening 214 and between the transparent layer 208 and the at least one light source 204′ but also between the non-transparent layer 206 and the at least one light source 204′.

FIG. 8 shows a cross-sectional view of a display area 100d in accordance with embodiments disclosed herein. The display area 100d of FIG. 8 is similar to the display area 100c of FIG. 7 except second transparent layer 212 extends across not only opening 214 and between the transparent layer 208 and the at least one light source 204′ but also between the transparent layer 208 and the non-transparent layer 212.

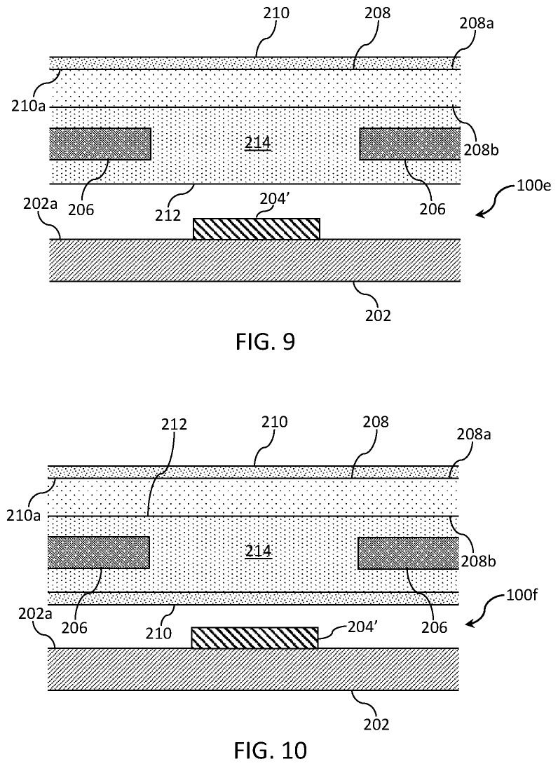

FIG. 9 shows a cross-sectional view of a display area 100e in accordance with embodiments disclosed herein. The display area 100e of FIG. 9 is similar to the display area 100d of FIG. 8 except second transparent layer 212 extends across not only opening 214, between the transparent layer 208 and the at least one light source 204′, and between the transparent layer 208 and the non-transparent layer 212, but also between the non-transparent layer 206 and the at least one light source 204′.

FIG. 10 shows a cross-sectional view of a display area 100f in accordance with embodiments disclosed herein. The display area 100f of FIG. 10 is similar to the display area 100e of FIG. 9 except the display area 100f includes an additional AR layer 210 that extends between the non-transparent layer 206 and the at least one light source 204′.

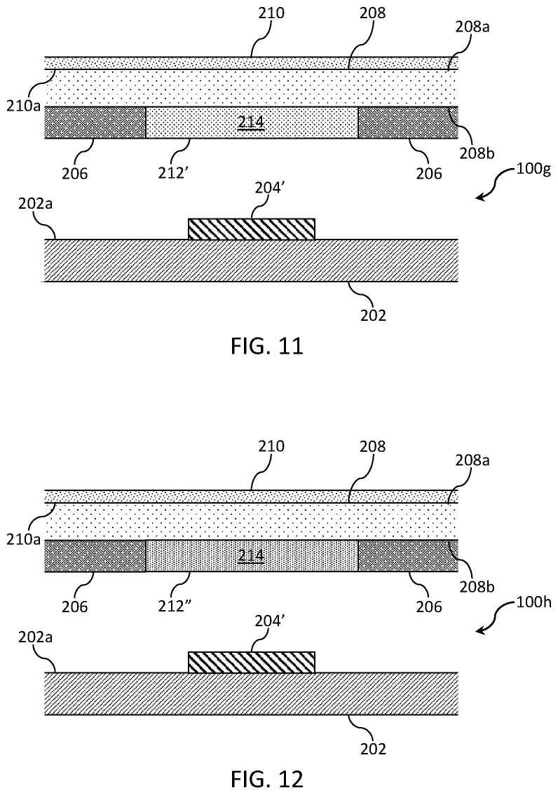

FIG. 11 shows a cross-sectional view of a display area 100g in accordance with embodiments disclosed herein. The display area 100g of FIG. 11 is similar to the display area 100b of FIG. 6 except second transparent layer 212′ is tinted.

FIG. 12 shows a cross-sectional view of a display area 100h in accordance with embodiments disclosed herein. The display area 100h of FIG. 12 is similar to the display area 100b of FIG. 6 except second transparent layer 212″ comprises a material with transformable transparency upon exposure to heat and/or light, such as thermo-chromic materials, photo-chromic materials, photoreactive materials, and light sensitive materials.

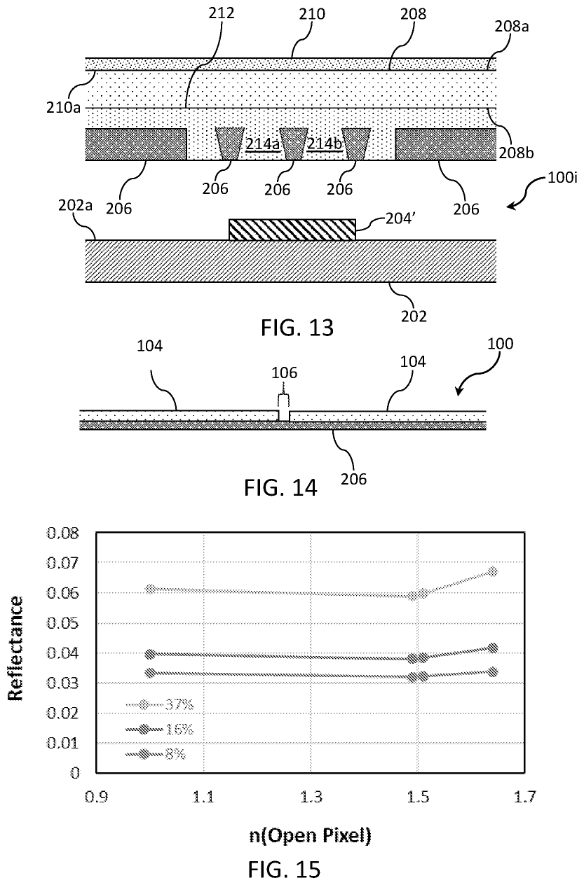

FIG. 13 shows a cross-sectional view of a display area 100i in accordance with embodiments disclosed herein. The display area 100i of FIG. 13 is similar to the display area 100b of FIG. 6 except opening 214 comprises a plurality of openings, including openings 214a and 214b, that are positioned between alternating strips of non-transparent layer 206.

FIG. 14 shows a cross-sectional view of a display area 100 in accordance with embodiments disclosed herein. Display area 100 includes tiles 104 and non-transparent layer 206, wherein seam 106 extends between adjacent tiles 104 and non-transparent layer 206 extends across seam 106. In certain exemplary embodiments, seam 106 can have a width such that the closet distance (or gap) between adjacent tiles ranges from about 25 micrometers to about 200 micrometers, such as from about 50 micrometers to about 100 micrometers.

In certain exemplary embodiments, transparent layer 208 comprises at least one material selected from glass materials, polymeric materials, ceramic materials, and sapphire. In certain exemplary embodiments, transparent layer 208 comprises glass.

In certain exemplary embodiments, non-transparent layer 206 comprises a black film, such as a carbon particle contained polymer resin. Non-transparent layer 206 may also comprise an absorbing/polarizing film, such as dye-doped liquid crystal or guest-host liquid crystal film.

In certain exemplary embodiments, non-transparent layer 206 can be adhered to transparent layer 208 according to methods known to persons having ordinary skill in the art, such as by lamination and solution coating, such as slot-die, bar coating, screen printing, inkjet printing, or spin-coating.

In certain exemplary embodiments, second transparent layer 212 comprises at least one material selected from glass materials, polymeric materials, ceramic materials, and sapphire. In certain exemplary embodiments, second transparent layer 212 comprises a polymeric material, such as optically clear adhesive (OCA), pressure sensitive adhesive (PSA), transparent polymer resins, such acrylates, meta acrylates, urethanes, polyesters, and epoxies, liquid crystal polymers, including reactive mesogen, and/or composites of the same.

In certain exemplary embodiments, AR layer comprises at least one material selected from magnesium fluoride, fluoropolymers, mesoporous silica nanoparticles, thin interference films, and layers with engineered surfaces, such as nanopatterned glasses.

When tinted, second transparent layer 212′ may comprise at least one tinting material selected from, for example, dyed tints, metalized tints, hybrid tents, carbon tints, and ceramic tints, as known to persons having ordinary skill in the art.

FIG. 15 is a chart showing a modeled estimation of reflectance as a function of pixel open area and transparent layer refractive index obtained by using ray-optic simulation of ambient light having a Lambertian distribution as known to persons having ordinary skill in the art, wherein the modeled configuration was similar to that shown in FIG. 6. With reference to FIG. 4, the term “pixel open area” refers to the percentage of the pixel area (i.e., percentage of the total area of pixel 200) made up by opening 214 (i.e., percentage of the total area of pixel 200 not encompassed or covered by non-transparent layer 206). As can be seen in FIG. 15, when the pixel open area is less than or equal to about 16% and the refractive index of transparent layer (e.g. transparent layer 208 and/or second transparent layer 212) is less than or equal to about 1.5, the reflectance value of the display area is less than about 0.04. In addition, when the pixel open area is less than or equal to about 8%, the reflectance value of the display area is less than about 0.04 over all transparent layer refractive indices. Accordingly, embodiments disclosed herein include those in which pixel open area is less than about 16%, such as less than about 8%, including from about 2% to about 16%, such as from about 4% to about 8%.

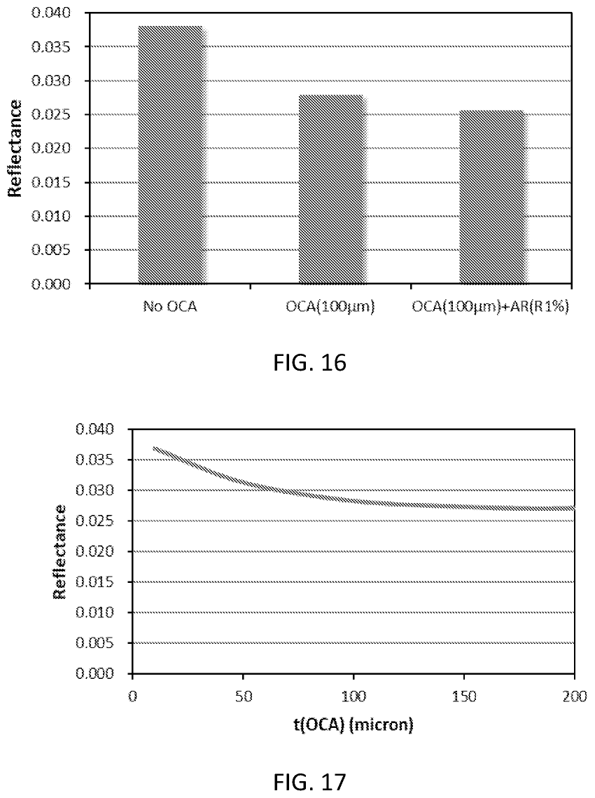

FIG. 16 is a chart showing reflectance in accordance with varying embodiments disclosed herein. Specifically, the bar on the left (labeled “no OCA”) of FIG. 16 references a configuration similar to that shown in FIG. 5 wherein no second transparent layer 212 extends across opening 214. The central bar (labeled “OCA(100 μm)”) references a configuration similar to that shown in FIG. 6 wherein a second transparent layer 212 having a thickness of about 100 micrometers and comprising OCA extends across opening 214. The bar on the right (labeled “OCA(100 μm)+AR(R1%)”) references a configuration similar to that shown in FIG. 10 wherein a second transparent layer 212 having a thickness of about 100 micrometers and comprising OCA extends across opening 214 and an additional AR layer 210 extends between the non-transparent layer 206 and light source 204′. As can be seen from FIG. 16, including the second transparent layer 212 and further including the additional AR layer 210 lowers the reflectance value of the display area.

FIG. 17 is a chart showing reflectance as a function of transparent layer thickness in accordance with embodiments disclosed herein. Specifically, FIG. 17 relates to the thickness of second transparent layer 212 extending across opening 214 (such as shown in FIG. 6) wherein second transparent layer 212 comprises OCA. As can be seen from FIG. 17, as the thickness of second transparent layer 212 increases, the reflectance value decreases.

Accordingly, embodiments disclosed herein include those in which the display area comprises a reflectance value of less than about 0.04, such as less than about 0.035, and further such as less than about 0.3, including from about 0.02 to 0.04, such as from about 0.025 to about 0.035.

Embodiments disclosed herein can, for example, enable display areas, such as micro-LED displays comprising a plurality of tiles having reduced seam or gap visibility. Such displays can also exhibit other desirable attributes such as an optical transmittance of greater than about 80%, a reflectance of less than about 5%, a haze of less than about 5%, and a viewing angle of ±90°.

It will be apparent to those skilled in the art that various modifications and variations can be made to embodiment of the present disclosure without departing from the spirit and scope of the disclosure. Thus, it is intended that the present disclosure cover such modifications and variations provided they come within the scope of the appended claims and their equivalents.

1. A display area comprising:
a plurality of tiles arranged in an array, each of the plurality of tiles comprising an optically transparent layer comprising a first major surface and an opposing second major surface, wherein each of the plurality of tiles comprises:
a substrate comprising a major surface facing the second major surface of the transparent layer;
a plurality of light sources positioned on the major surface of the substrate; and
a non-transparent layer between the transparent layer and the plurality of light sources, the non-transparent layer comprising an opening extending over an area between at least one of the plurality of light sources and the transparent layer; wherein
a seam extends between adjacent tiles of the plurality of tiles; and
the non-transparent layer extends across the seam.

2. The display area of claim 1, wherein the transparent layer comprises glass.

3. The display area of claim 1, wherein the plurality of light sources comprise light emitting diodes (LEDs).

4. The display area of claim 3, wherein the opening extends over an area comprising a red-green-blue (RGB) LED chip.

5. The display area of claim 1, wherein the non-transparent layer is adhered to the transparent layer.

6. The display area of claim 1, wherein the non-transparent layer comprises a black film or an absorbing/polarizing film.

7. The display area of claim 1, wherein each of the plurality of tiles further comprises at least one anti-reflective (AR) layer.

8. The display area of claim 7, wherein the AR layer comprises a major surface facing the first major surface of the transparent layer.

9. The display area of claim 7, wherein the AR layer extends between the non-transparent layer and the plurality of light sources.

10. The display area of claim 7, wherein the AR layer comprises at least one material selected from magnesium fluoride, fluoropolymers, and mesoporous silica nanoparticles.

11. The display area of claim 1, wherein each of the plurality of tiles further comprises at least a second transparent layer, the second transparent extending between the transparent layer and the plurality of light sources.

12. The display area of claim 11, wherein the second transparent layer extends across the opening.

13. The display area of claim 12, wherein the second transparent layer extends between the non-transparent layer and the plurality of light sources.

14. The display area of claim 12, wherein the second transparent layer extends between the transparent layer and the non-transparent layer.

15. The display area of claim 11, wherein the second transparent layer comprises a polymeric material.

16. The display area of claim 11, wherein the second transparent layer is tinted or comprises a material with transformable transparency.

17. The display area of claim 1, wherein the opening comprises a plurality of openings.

18. The display area of claim 1, wherein the display area comprises a reflectance value of less than about 0.04.

19. A method of making the display area of claim 1 comprising positioning the transparent layer and the non-transparent layer such that the opening extends over an area between at least one of the plurality of light sources and the transparent layer.

20. A display area comprising:
At least one tile comprising an optically transparent layer comprising a first major surface and an opposing second major surface, wherein the at least one tile comprises:
a substrate comprising a major surface facing the second major surface of the transparent layer;
a plurality of light sources positioned on the major surface of the substrate; and
a non-transparent layer between the transparent layer and the plurality of light sources, the non-transparent layer comprising an opening extending over an area between at least one of the plurality of light sources and the transparent layer.

21. The display area of claim 20, wherein the non transparent layer comprises a black film or an absorbing/polarizing film.

22. An electronic device comprising the display area of claim 1.
